(19) United States
(12) Patent Application Publication
(10) Pub. No.: US 2011/0048486 A1
(43) Pub. Date: Mar. 3, 2011

(54) THERMOELECTRIC MODULE

(75) Inventors: Osamu SENSUI, Hiratsuka-shi (JP); Akio Konishi, Hiratsuka-shi (JP)

(73) Assignee: KELK LTD., Hiratsuka-shi (JP)

(21) Appl. No.: 12/862,937

(22) Filed: Aug. 25, 2010

(30) Foreign Application Priority Data
Aug. 28, 2009 (JP) 2009-198979

(51) Int. Cl. H01L 35/30

(52) U.S. Cl. 136/203

(57) ABSTRACT

A thermoelectric module includes: a plurality of thermoelectric elements that is electrically series-connected via a plurality of electrodes; and a pair of substrates on which the plurality of electrodes are formed on facing surfaces of the pair of substrates, the pair of substrates being provided perpendicularly to a heat transfer direction with the plurality of thermoelectric elements being interposed. An electrode of an upper substrate includes a first electrode having a size enough to electrically connect the thermoelectric elements that are spaced apart from each other by a distance corresponding to an area equivalent to an adjacent pair of the thermoelectric elements. An electrode of a lower substrate is provided correspondingly to a maximum placement number of the thermoelectric elements interposed between the substrates, and also has a size enough to electrically connect the adjacent pair of the thermoelectric elements.

The entire disclosure of Japanese Patent Application No. 2009-198979 filed Aug. 28, 2009 is expressly incorporated by reference herein.

### BACKGROUND OF THE INVENTION

1. Field of the Invention

The present invention relates to a thermoelectric module with use of Peltier effect.

2. DESCRIPTION OF RELATED ART

There has been conventionally known a thermoelectric module in which a plurality of thermoelectric elements (a P-type thermoelectric element and an N-type thermoelectric element) are held between a pair of substrates and bonded thereto, the thermoelectric module cooling or heating an object by supplying electricity between the thermoelectric elements. The thermoelectric elements are disposed so as to be electrically series-connected to each other via electrodes provided on each of the substrates. When electricity is supplied to respective thermoelectric elements, a unidirectional heat transport is generated between the substrates by Peltier effect.

An endothermic reaction is generated on one of the pair of substrates and a heat-release reaction is generated on the other of the pair of substrates. Based on this, an object to be cooled is attached to the substrate having the endothermic reaction and a heat sink is attached to the substrate having the heat-release reaction, whereby the object to be cooled is temperature-controlled. At this time, generally, a metallization layer is formed in advance on surfaces of the substrates, which are formed of alumina and the like, in order to facilitate direct-soldering of the object to the substrates. The object and the heat sink are installed on the surfaces of the metallization layer through a solder layer or an adhesive.

A comparison between a coefficient of thermal expansion of the substrates and that of the solder layer reveals that the coefficient of thermal expansion of the solder layer is larger than that of the substrates by three times or more. Accordingly, when both temperatures of the substrates and the solder layer are lowered, the solder layer is more shrunk than the substrates, so that the substrates are warped. At this time, each of the substrates is warped from thermoelectric elements disposed at the center of the substrates. Accordingly, a displacement of warpage of respective substrates becomes larger in accordance with the distance from the center and stress generated on the elements on an outer circumference is enlarged, so that the thermoelectric elements may be damaged by the displacement and stress.

Accordingly, it has been known to prevent damage of the theimoelectric elements by eliminating the thermoelectric elements disposed at a predetermined area at the center of the substrates and suppressing stress due to warpage generated on the substrates (see, for instance, Patent Literature 1: JP-A-2009-129968).

In Patent Literature 1, since the thermoelectric elements disposed at the predetennined area at the center of the substrates are eliminated, an elongated and different-shaped electrode spanning over the area eliminated with the thermoelectric elements, is formed on each of the substrates holding the thermoelectric elements, thereby interconnecting a pair of thermoelectric elements largely separated from each other.

However, since a size and a shape of the area in which the thermoelectric elements are eliminated, in other words, the number of pairs of the thermoelectric elements to be disposed between the substrates (herein, “the number of pairs” means a total number counted for each of a pair of P-type thermoelectric element and N-type thermoelectric element which are bonded to a single electrode) and layout thereof differ depending on a design of the thermoelectric module, substrates having various electrode patterns for different designs are required as an upper substrate and a lower substrate, which increases manufacturing cost.

### SUMMARY OF THE INVENTION

An object of the invention is to provide a thermoelectric module whose manufacturing cost is reduced while stress generation caused by warpage of a substrate being suppressed.

A thermoelectric module according to an aspect of the invention includes: a plurality of thermoelectric elements that is electrically connected to each other via a plurality of electrodes; and a pair of substrates including a first substrate and a second substrate on which the plurality of electrodes are formed on facing surfaces, the pair of substrates being provided perpendicularly to a heat transfer direction with the plurality of thermoelectric elements being interposed, in which the plurality of electrodes formed on the first substrate of the pair of substrates include a bypass electrode having a size enough to electrically connect a pair of the thermoelectric elements that are spaced apart by a distance corresponding to an area of one of the thermoelectric elements or more, and the plurality of electrodes foimed on the second substrate of the pair of substrates are provided correspondingly to a maximum placement number of the plurality of thermoelectric elements interposed between the pair of substrates and have a size enough to electrically connect an adjacent pair of the thermoelectric elements.

Herein, “adjacent” means that, when the then ioelectric elements are located at the maximum placement number, the thermoelectric elements are positioned next to each other, irrespective of an alignment direction. Accordingly, in the aspect of the invention, when the thermoelectric elements are located at the maximum placement number, the electrode that electrically connects the pair of the thermoelectric elements is provided as an electrode having the smallest shape.

In the thermoelectric module according to the aspect of the invention, the bypass electrode includes a plurality of adjacent bypass electrodes, and bypass-electrode aggregation portion formed by the plurality of adjacent bypass electrodes is surrounded by an electrode having a size enough to electrically connect an adjacent pair of the thermoelectric elements.

Herein, “bypass-electrode aggregation portion” means a portion on which a plurality of the bypass electrodes are aggregated, irrespective of a size and shape thereof.

In the thermoelectric module according to the aspect of the invention, an object to be cooled is installed on a side opposite to a side of the first or second substrate which the plurality of electrodes are formed, the plurality of thermoelectric elements are sparsely o densely located in accordance with installation layouts of the object to be cooled, and the bypass electrode has a size enough to connect the pair of theillioelectric elements at dense parts that are located over a sparse part.

According to the aspect of the invention, the bypass electrodes are only provided on the first substrate and the electrodes corresponding to the maximum placement number of the thermoelectric elements are provided on the second substrate. Accordingly, when various designs, in which warpage of the substrates, endothermic efficiency and the like are taken into consideration, are present for disposing the thermoelectric elements, it is just necessary to change a shape and the like of the bypass electrodes. Specifically, it is just necessary to only change the first substrate on which the bypass electrodes are formed.

Accordingly, the second substrate, on which electrodes corresponding to the maximum placement number of the thermoelectric elements are provided, can be used in common with a thermoelectric module having a different design, thereby reducing the kind of parts to save the manufacturing cost. Depending on the number, shape and location of the bypass electrodes, i.e., the number and location of the thermoelectric elements to be eliminated, stress generation caused by warpage of the substrate can be suppressed.

In the aspect of the invention, when the plurality of the bypass electrodes are aggregated in a predetermined area on the first substrate, and thus obtained bypass-electrode aggregation portion is surrounded by other small electrodes, the thermoelectric elements located, for instance, substantially at the center of the substrate as the starting point of warpage thereof are not necessary. Accordingly, even when the substrate is warped from the starting point, i.e., the eccentrically arranged thermoelectric elements, a distance between the starting point of the warpage and an outer circumference of the substrate is shorter than that between the outer circumference and the starting point of warpage located at the center. Accordingly, warpage displacement and stress can be further reduced.

Incidentally, the thermoelectric module according to the aspect of the invention can be provided as one capable of transporting heat from the first substrate to the second substrate by Peltier effect, thereby temperature-controlling a heat-generating object to be cooled by installing the object on the first substrate. In such a thermoelectric module, by densely locating the thermoelectric elements in an area where the object to be cooled generates a large amount of heat and by sparsely locating the thermoelectric elements in an area where the object to be cooled generates a small amount of heat and locating the bypass electrodes corresponding to the sparse area, the necessary number of the thermoelectric elements can be located in the necessary area and endothermic efficiency can be improved.

### BRIEF DESCRIPTION OF THE DRAWINGS

FIG. 1 is a cross sectional view showing a thermoelectric module and a semiconductor laser unit according to a first exemplary embodiment of the invention.

FIG. 2 is a plan view seen from II-II line of FIG. 1.

FIG. 3 is a plan view seen from line of FIG. 1.

FIG. 4 is an overall plan view of a semiconductor laser unit.

FIG. 5 is a plan view when a maximum number of thermoelectric elements are disposed between the substrates.

FIG. 6 is a cross sectional view showing a thermoelectric module according to a second exemplary embodiment of the invention.

FIG. 7 is a plan view seen from VII-VII line of FIG. 6.

FIG. 8 is a cross sectional view showing a thermoelectric module according to a third exemplary embodiment of the invention.

FIG. 9 is a plan view seen from IX-IX line of FIG. 8.

FIG. 10 is a cross sectional view showing a thermoelectric module according to a fourth exemplary embodiment of the invention.

FIG. 11 is a plan view seen from XI-XI line of FIG. 10.

FIG. 12 is a cross sectional view showing a thermoelectric module according to a fifth exemplary embodiment of the invention.

FIG. 13 is a plan view seen from XIII-XIII line of FIG. 12.

### DETAILED DESCRIPTION OF PREFERRED EMBODIMENT(S)

### First Exemplary Embodiment

A first exemplary embodiment of the invention will be described below with reference to the attached drawings.

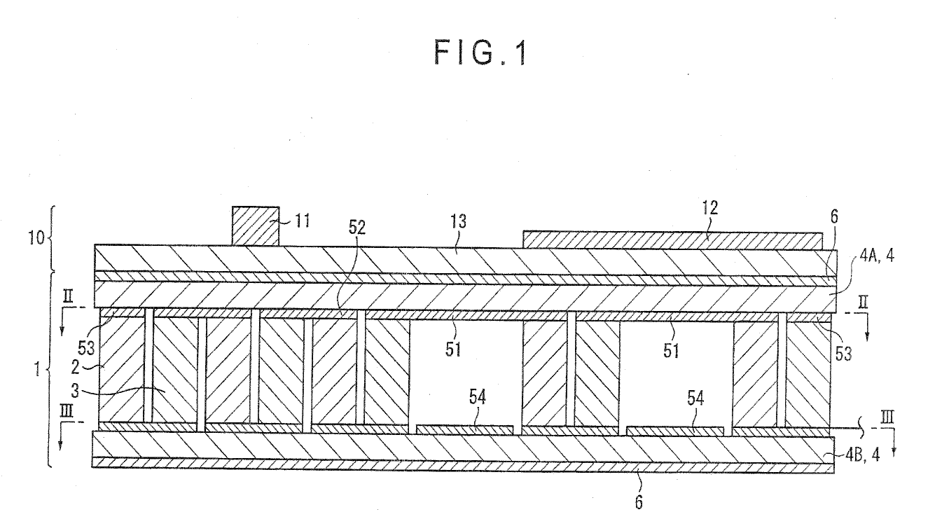

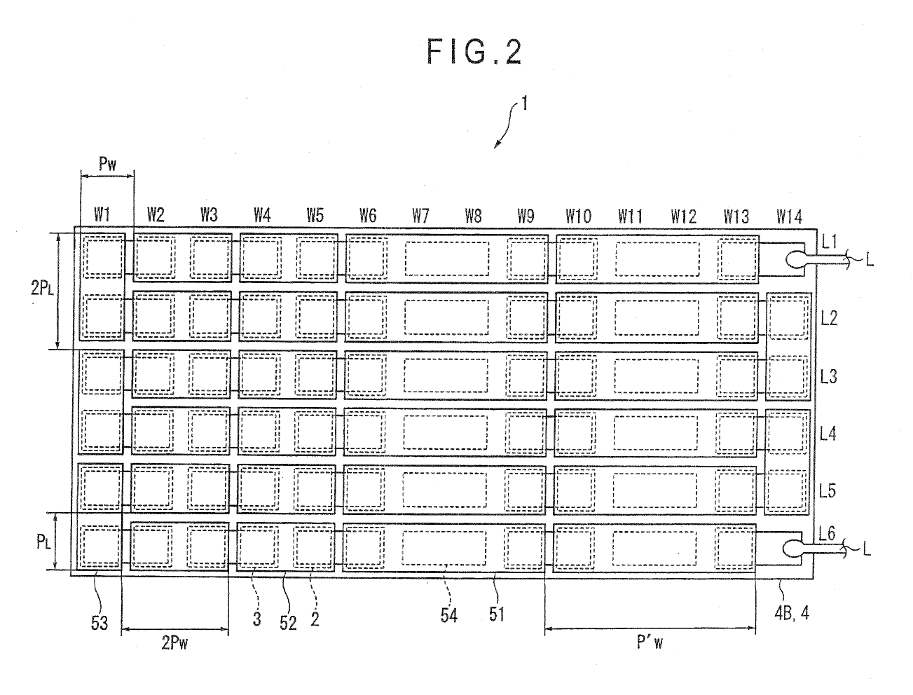

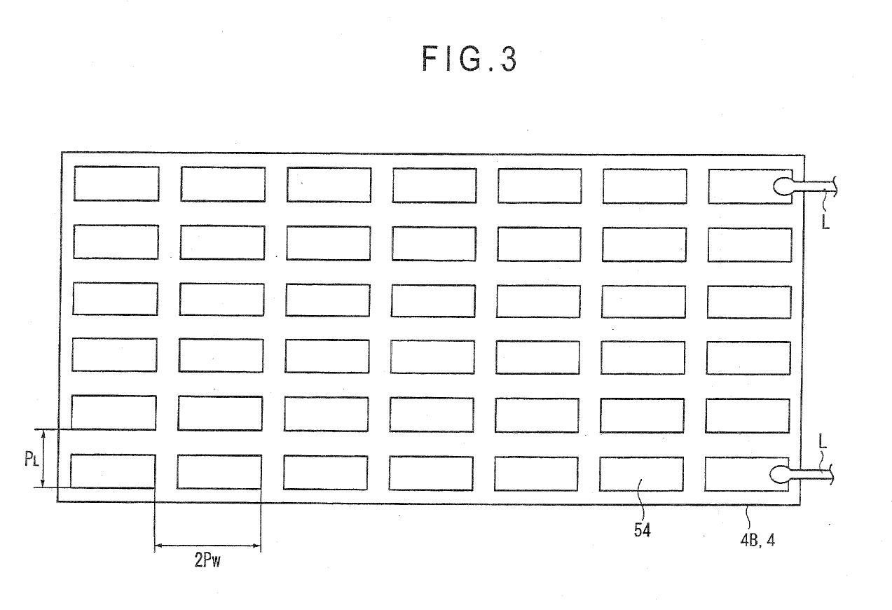

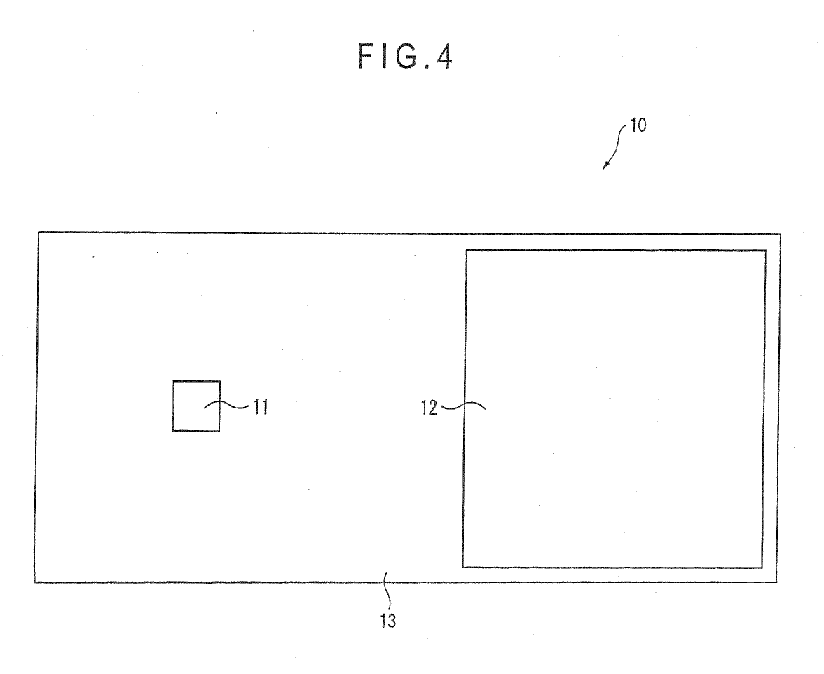

FIG. 1 is an overall plan view of a thermoelectric module 1 and a semiconductor laser unit 10. FIG. 2 is a plan view seen from an arrow of II-II of FIG. 1, in which an upper substrate 4A and a metallization layer 6 (described below) are eliminated from the thermoelectric module 1 shown in FIG. 1. FIG. 3 is a plan view seen from an arrow of III-III of FIG. 1. FIG. 4 is an overall plan view of the semiconductor laser unit 10.

The thermoelectric module 1 substantially includes, as shown in FIGS. 1 and 2, a plurality of P-type thermoelectric elements 2 and N-type thermoelectric elements 3 and a pair of substrates 4 that are disposed perpendicularly to a heat transfer direction (described below) and interposed by the thermoelectric elements 2 and 3.

Each of P-type thermoelectric elements 2 includes: a P-type thermoelectric material containing bismuth (Bi) and tellurium (Te); and a diffusion prevention layer containing any one of molybdenum (Mo), tungsten (W), niobium (Nb), tantalum (Ta) and Nickel (Ni).

Each of N-type thermoelectric elements 3 includes: an N-type thermolectric material containing bismuth (Bi) and tellurium (Te); and the same diffusion prevention layer as that of the P-type thermoelectric element 2.

As shown in FIG. 1, the substrates 4 include an upper substrate 4A that is disposed at an upper side of FIG. 1, serving as a first substrate; and a lower substrate 4B that is disposed at a lower side of FIG. 1, serving as a second substrate. The substrates 4 are made of ceramics which is typically an insulating material, and formed of alumina (Al₂O₃), alumina nitride (AN), silicon carbide (SiC) and the like. Alternatively, the substrates 4 may be made of a resin such as polyimide.

A metallization layer 6 is respectively formed on an upper surface of the upper substrate 4A and a lower surface of the lower substrate 4B. The metallization layer 6 is provided by laminating copper (Cu), nickel (Ni) and gold (Au). The semiconductor laser unit 10 (described below) is bonded to the metallization layer 6 of the upper substrate 4A through a solder layer (not shown). A heat sink (not shown) provided with a plurality of heat release fins or a metal member such as a package is bonded to a substantially whole surface of the metallization layer 6 of the lower substrate 4B through a solder layer (not shown) or an adhesive.

In such a thermoelectric module 1, when electricity is supplied to each of the thermoelectric elements 2 and 3, heat is unidirectionally transferred between the substrates 4 by Peltier effect, in which an endothermic reaction is generated on the upper substrate 4A and a heat-release reaction is generated on the lower substrate 4B. It should be noted that, depending on a direction in which electricity is supplied to each of the thermoelectric elements 2 and 3, a heat release reaction is generated on the upper substrate 4A and an endothermic reaction is generated on the lower substrate 4B.

Accordingly, in this exemplary embodiment in which the thermoelectric elements 2 and 3 are interposed between the substrates 4A and 4B aligned in a heat transfer direction thereof, heat of the semiconductor laser unit 10 is absorbed through the upper substrate 4A by attaching the semiconductor laser unit 10 to the upper substrate 4A having an endothermic reaction. At the same time, the absorbed heat is transported to the lower substrate 4B through each of the thermoelectric elements 2 and 3, and then released outward by a heat sink and the like, thereby cooling the semiconductor laser unit 10.

A plurality of first electrodes 51 to third electrodes 53, to which an upper end of each of the thermoelectric elements 2 and 3 is bonded, are provided on a lower surface of the upper substrate 4A. A plurality of fourth electrodes 54, to which a lower end of each of the thermoelectric elements 2 and 3 is bonded, are provided on an upper surface of the lower substrate 4B. Among the first electrodes 51 to fourth electrodes 54, the first substrates 51 provided on the upper substrate 4A are bypass electrodes according to the invention.

The first electrodes 51 to fourth electrode 54 are, for instance, nickel (Ni)-plated by a copper plating method, or made of copper plated with nickel (Ni) and gold (Au). The first electrodes 51 to fourth electrodes 54 all are rectangular, but each of the first electrodes 51 has a different length in a longitudinal direction from each of the second electrodes 52 to fourth electrodes 54. The each of the second electrodes 52 to fourth electrodes 54 has the same shape and length. The second electrodes 52 and the fourth electrodes 54 are directed differently from the third electrodes 53 by 90 degrees.

In FIGS. 2 and 3, it should be noted that a size of each of the fourth electrodes 54 is drawn in a slightly smaller size than that of the second and third electrodes 52 and 53 in order to clarify positions of the fourth electrodes 54 against those of the first to third electrodes 51 to 53.

Moreover, the longitudinal direction and a transversal direction of each of the first, second and fourth electrodes 51, 52 and 54 are the same as those of the substrates 4. A longitudinal dimension of each of the first electrodes 51 is represented by P_{w}′ including gaps between adjacent electrodes. A longitudinal dimension of each of the second and fourth electrodes 52 and 54 is represented by 2P_{w} including gaps between adjacent electrodes. Similarly, a transversal dimension of each of the first, second and fourth electrodes 51, 52 and 54 is represented by P_{L}.

A longitudinal dimension of each of the third electrodes 53 is represented by 2P_{L} including gaps between adjacent electrodes. Similarly, a transversal dimension thereof is represented by P. The longitudinal dimension of each of the first electrodes 51 is larger than those of the second and fourth electrodes 52 and 54.

As described above, in this exemplary embodiment, the second to fourth electrodes 52 to 54 have the same shape and size. When the dimension P_{w} or P_{L} is altered, the second to fourth electrodes 52 to 54 are different from the third electrodes 53 in size.

In the above thermoelectric module 1, as shown in FIG. 1, the first to the third electrodes 51 to 53 on the upper substrate 4A (not shown in FIG. 1) are disposed in a manner to be alternated with the fourth electrodes 54 on the lower substrate 4B. With this arrangement, the thermoelectric elements 2 and 3 are electrically series-connected through the first to fourth electrodes 51 to 54. A lead wire L is connected to the fourth electrodes 54 disposed on both ends in a connection direction. Instead of the lead wire L of this exemplary embodiment, a wire bonding method by using an electrode pad and a post electrode may be used for connection.

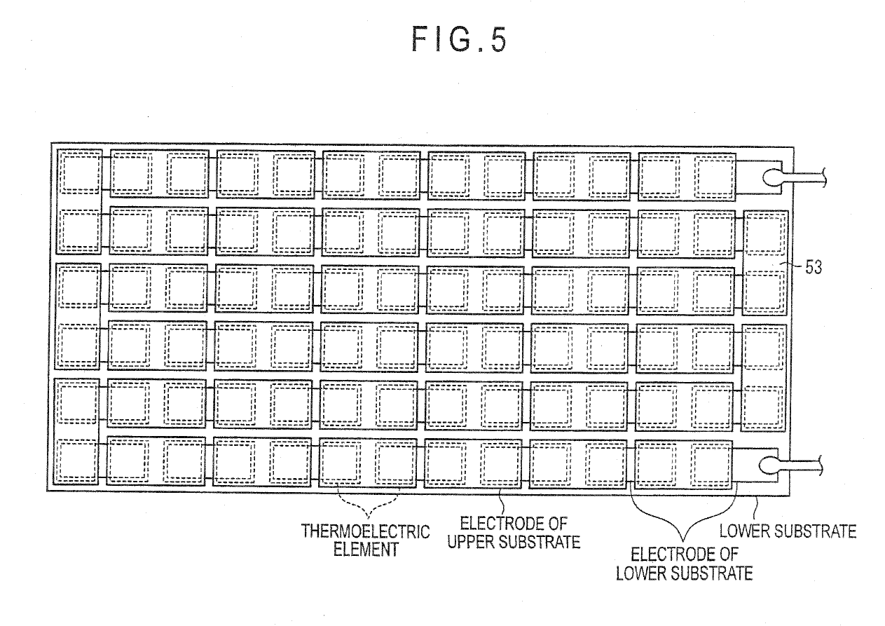

Numerals W1 to W14 and L1 to L6 in FIG. 2 respectively represent a row number (W1 to W14) and a line number (L1 to L6) of positions of thermoelectric elements 2 and 3. The same applies for numerical numbers shown in the drawings to be used for explanation of the following exemplary embodiments. Moreover, as shown in FIG. 5, the thermoelectric elements of 84 at the maximum, i.e., 42 pairs at the maximum can be provided in principle on the upper and lower substrates by using all the lines and the rows. In FIG. 5, actually-used thermoelectric elements are 41 pairs since electricity is supplied by the lead wire. However, a maximum placement number of the pairs on the substrates is 42 pairs.

However, 6 pairs (corresponding to W7 and W8 rows) at the center and 6 pairs (corresponding to W11 and W12 rows) on the right, i.e., 12 pairs in total of the thermoelectric elements 2 and 3 are eliminated in this exemplary embodiment, as shown in FIG. 2. Consequently, 29 pairs of the thermoelectric elements 2 and 3 are provided between the substrates 4. On the other hand, as shown in FIG. 3, the fourth electrodes 54 on the lower substrate 4B are provided correspondingly to the maximum placement number of the pairs, as is the case in which 41 pairs of the thermoelectric elements 2 and 3 are located in FIG. 5.

On the upper substrate 4A, the first electrodes 51 are provided correspondingly to 12 positions from which the thermoelectric elements 2 and 3 are eliminated. The first electrodes 51 are provided over the area corresponding to the eliminated thermoelectric elements 2 and 3 and are formed longer than the second electrodes 52 along the longitudinal direction of the upper substrate 4A. In other words, the first electrodes 51 serving as the bypass electrodes are electrically connected to the thermoelectric elements 2 and 3 in W6 and W9 rows, which are spaced apart by W7 and W8 rows. The first electrodes 51 are also electrically connected to the thermoelectric elements 2 and 3 in W10 and W13 rows, which are spaced apart by W11 and W12 rows.

For a detailed explanation of other electrodes, at a left end of FIG. 2, three third electrodes 53 are located in a single row on the upper substrate 4A while longitudinal directions of the three third electrodes 53 are aligned along a transversal direction of the upper substrate 4A. In other words, in W1 row, the third electrodes electrically connect the thermoelectric elements 2 and 3 in L1 and L2 lines, those in L3 and L4 lines and those in L5 and L6 lines to each other.

On an inner side (a right side) of the third electrodes 53, the second electrodes 52 are located with longitudinal directions thereof aligned along a longitudinal direction of the upper substrate 4A, the number of the second electrodes 52 being 12 in total in two rows of six lines. Accordingly, in L1 to L6 lines, the second electrodes connect the thermoelectric elements 2 and 3 in W2 and W3 rows as well as those in W4 and W5 rows.

The first electrodes 51 are located on a right side of the second electrodes 52, the number of the first electrodes 51 being 12 in total in two rows of six lines in the same manner as described above. At a right end of the upper substrate 4A, two third electrodes 53 are located in a single row with longitudinal directions thereof aligned along a transversal direction of the upper substrate 4A. The two third electrodes 53 are located around a center of the transversal direction of the upper substrate 4A and connect the thermoelectric elements 2 and 3 in L2 and L3 lines and those in L4 and L5 lines to each other in W14 row. Accordingly, no electrode is provided at corners on the right end of the upper substrate 4A. Consequently, a half of each of the fourth electrodes 54 at the corners on the lower substrate 4B is exposed for connecting the lead wire L.

On the other hand, as shown in FIG. 3, on the lower substrate 4B, the fourth electrodes 54 are provided with longitudinal directions thereof aligned along the longitudinal direction of the lower substrate 4B in seven rows of six lines, which corresponds to the maximum placement number of the thermoelectric elements 2 and 3.

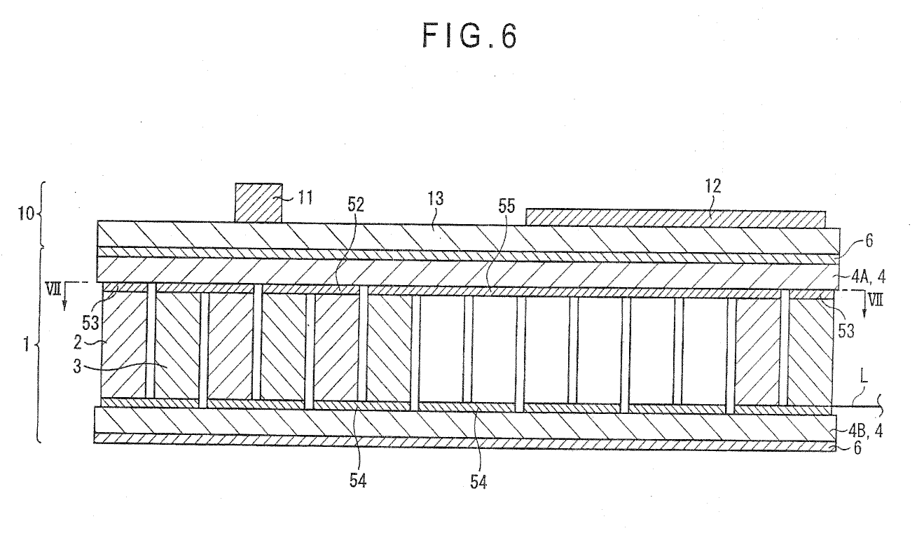

Such a lower substrate 4B is used in common for a thermoelectric module of alternative design in which the number of thermoelectric elements 2 and 3 to be practically provided is changed from 29 pairs, as long as the maximum placement number of the thermoelectric elements 2 and 3 is not changed. In addition, the lower substrate 4B is used in common as a lower substrate 4B of a second and other exemplary embodiments (see FIGS. 6 to 13) in which a layout of the thermoelectric elements 2 and 3 is altered though the number of thermoelectric elements 2 and 3 to be practically provided stays the same (29 pairs).

In FIGS. 1 and 4, the semiconductor laser unit 10 exemplarily includes a semiconductor laser diode (LD) 11 and an optical modulator 12 as objects to be cooled and other parts (not shown) which are installed by soldering and the like on a submount 13 formed on the upper surface of the upper substrate 4A. However, the arrangement of the semiconductor laser unit 10 is not limited to one shown in FIGS. 1 and 4.

The LD 11 is primarily used for optical communication, and additionally for an optical disc player and the like. The LD 11 oscillates and outputs a light. The light is intensity-modulated by the optical modulator 12 and is output from an emitting portion (not shown). A heat generation amount of the LD 11 is larger than that of the optical modulator 12. The LD 11 is installed at a center of an area corresponding to W1 to W6 rows of the thermoelectric module 1. The optical modulator 12, which generates less heat than the LD 11, is installed correspondingly to W9 to W14 rows of the thermoelectric module 1.

As described above, the LD 11 has the larger generation amount in spite of the smaller installation area. Accordingly, by densely providing 18 pairs of the thermoelectric elements 2 and 3 in the area corresponding to W1 to W6 rows, the thermoelectric elements 2 and 3 can reliably absorb the heat from the LD 11 to favorably cool the LD 11.

In contrast, since the optical modulator 12 generates less heat in spite of the large installation area in W9 to W14 rows, the heat from the optical modulator 12 can be sufficiently absorbed even in a sparse layout in which thermoelectric elements 2 and 3 are not provided in W11 and W12 rows. Further, since no object to be cooled is present in an area between the LD 11 and the optical modulator 12, the thermoelectric elements 2 and 3 are not provided also in W7 and W8 rows corresponding to such an area, resulting in a sparse layout.

As described above, in the thermoelectric module 1 of this exemplary embodiment, the thermoelectric elements 2 and 3 are densely or sparsely provided in accordance with installation layouts of the LD 11 and the optical modulator 12 which are to be cooled. Accordingly, endothermic efficiency of the installed thermoelectric elements 2 and 3 can be improved and the thermoelectric module 1 can be reduced in cost by eliminating excessive thermoelectric elements 2 and 3.

Because the thermoelectric elements 2 and 3 are not present in W7 and W8 rows at the center of the substrates 4A and 4B, the substrates 4A and 4B are warped starting from a position offset from the center thereof toward an outside of the longitudinal direction thereof Accordingly, displacements at both ends and stress at the center can be lowered, thereby suppressing damage on the substrates 4A and 4B.

In this exemplary embodiment, the first electrodes 51 are applied in a manner to bridge over the area where the thermoelectric elements 2 and 3 are sparse. However, an electrode pattern having the above first electrodes 51 is applied only for the upper substrate 4A. On the lower substrate 4B, the fourth electrodes 54 are provided correspondingly to the maximum placement number of the thermoelectric elements 2 and 3.

In other words, in a thermoelectric module of a different design in which the thermoelectric elements 2 and 3 are located in consideration of warpage of the substrates 4 and the like as described in the second and other exemplary embodiments, by providing such different-shaped first electrodes 41 only on the upper substrate 4A, it is only necessary to alter the electrode pattern of the upper substrate 4A according to the design and to constantly use the lower substrate 4B having the same electrode pattern. Accordingly, even if the thermoelectric module has the different design, the substrate 4B can be used in common by changing the substrate 4A, thereby further reducing a manufacturing cost.

### Second Exemplary Embodiment

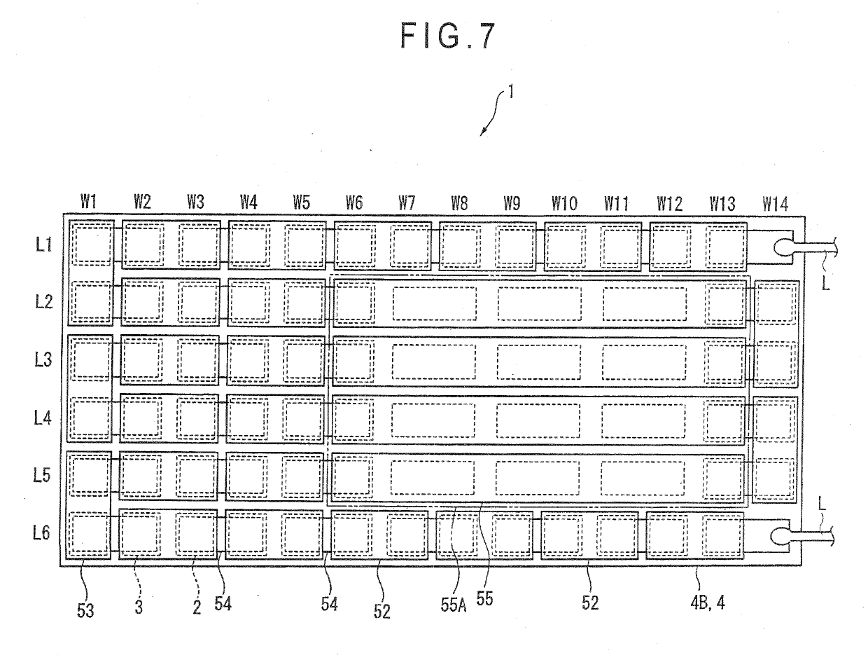

A second exemplary embodiment of the invention will be described below with reference to FIGS. 6 and 7.

In the following description, the same structure and components as those in the first exemplary embodiment are indicated by the same reference symbols or numerals for omitting or simplifying the detailed description thereof. The electrode pattern of the fourth electrodes 54 formed on the lower substrate 4B is the same as that in the first exemplary embodiment The same applies for other exemplary embodiments described below.

In the first exemplary embodiment, the first electrodes 51 are provided at 12 positions on the upper substrate 4A in a manner to bridge over an area corresponding to a pair of the thermoelectric elements 2 and 3. However, in the second exemplary embodiment, the fifth electrodes 55 are formed at four positions as a bypass electrode to bridge over an area occupied by three pairs of the thermoelectric elements 2 and 3 as shown in FIGS. 6 and 7. This is a difference between the first and the second exemplary embodiments.

Specifically, in the second exemplary embodiment, the thermoelectric elements 2 and 3 are eliminated by 12 pairs (in L2 to L5 lines of W7 to W12) and 29 pairs of the thermoelectric elements 2 and 3 are provided between the substrates 4A and 4B. The area where the thermoelectric elements 2 and 3 are eliminated is closer to the optical modulator 12 than the substrates 4A and 4B and requires relatively gentle absorption of heat.

Moreover, the area where the thermoelectric elements 2 and 3 are eliminated is a bypass-electrode aggregation portion 55A in which four fifth electrodes 55 are aggregated. A circumference of the fifth electrodes 55 is surrounded by the second electrodes. In other words, a circumference of the sparse area is surrounded by the thermoelectric elements 2 and 3. The fifth electrodes 55 electrically connect the thermoelectric elements 2 and 3 provided in W6 and W13 rows to each other in L2 to L5.

According to the thermoelectric module 1 of the second exemplary embodiment, the following advantages can be obtained in addition to the same advantages of the first exemplary embodiment.

In this exemplary embodiment, a plurality of different-shaped fifth electrodes 55 are aggregated in a predetermined area which requires gentle absorption of heat, while, in a manner to correspond to the area, an area where the thermoelectric elements 2 and 3 are eliminated is formed. The area and the bypass-electrode aggregation portion 55A corresponding to the area are respectively surrounded by the second electrodes 52 and the thermoelectric elements 2 and 3. Accordingly, although the number of the pairs of the thermoelectric elements 2 and 3 in use is the same as that of the first exemplary embodiment, increase in stress caused by warpage of the substrates 4A and 4B can be more reliably prevented than in the first exemplary embodiment.

In this exemplary embodiment, in case of warpage of the substrates 4A and 4B, starting points are W6 and W13 rows. A distance between the starting points and outer circumferences of the substrates 4A and 4B is shorter, particularly on the right, than a distance between a center and the outer circumference of the substrates 4. Accordingly, a displacement by warpage on the right can be reliably reduced, thereby decreasing the stress at the center. Further, against warpage of the substrates 4A and 4B, the second electrodes 52 provided in W6 to W13 rows of L1 line are favorably balanced with the second electrodes 52 provided in W6 to W13 rows of L6 line, thereby significantly decreasing the displacement of warpage.

### Third Exemplary Embodiment

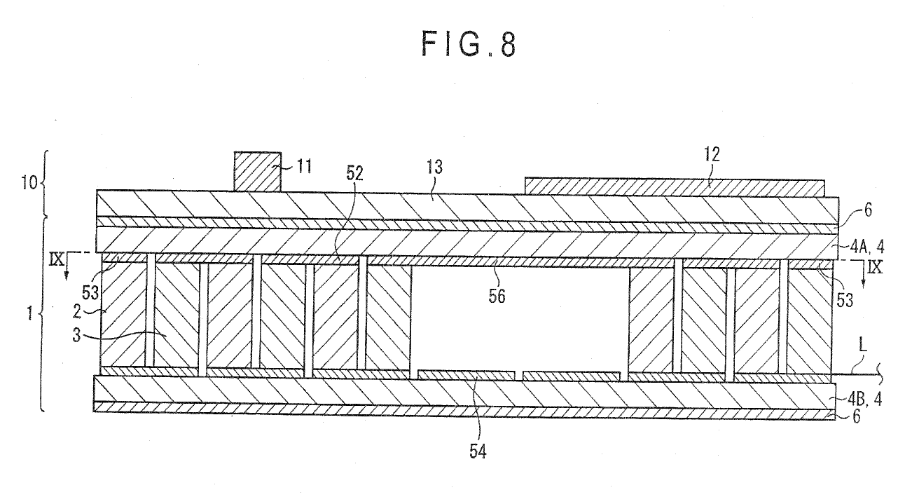

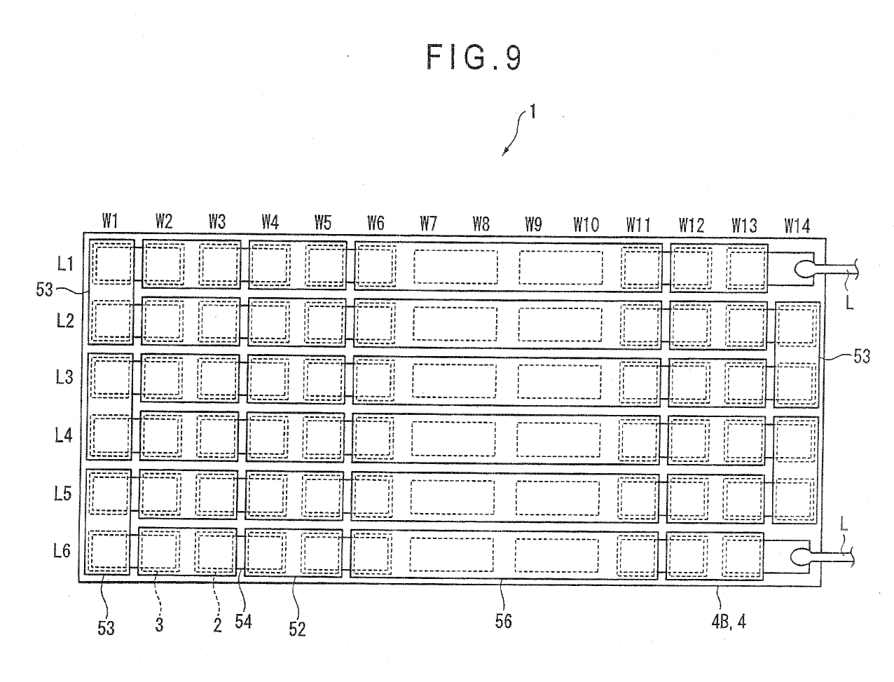

A third exemplary embodiment of the invention will be described below with reference to FIGS. 8 and 9.

In the third exemplary embodiment, six sixth electrodes 56 are provided as a bypass electrode that bridges over an area corresponding to two pairs of the thermoelectric elements 2 and 3.

Accordingly, in the third exemplary embodiment, the thermoelectric elements 2 and 3 are eliminated by 12 pairs (W7 to W10 rows) and 29 pairs of the thermoelectric elements 2 and 3 are provided between the substrates 4A and 4B. As in the first and second exemplary embodiments, the bypass electrodes are also provided correspondingly to the area where the thermoelectric elements 2 and 3 are eliminated.

The sixth electrodes 56 electrically connect a single pair of the thermoelectric elements 2 and 3 to each other which is provided in a manner to bridge over the eliminated thermoelectric elements 2 and 3. Specifically, in L1 to L6, the sixth electrodes 56 connect the thermoelectric elements 2 and 3 provided in W6 and W11 rows.

In the thermoelectric module 1 of the third exemplary embodiment, the thea inoelectric elements 2 and 3 are more densely provided in the area of W 11 to W14 corresponding to the optical modulator 12 than in the second exemplary embodiment, so that an endothermic efficiency of the optical modulator 12 can be improved. Although not to the extent of the second exemplary embodiment, the substrate warpage can be reduced near the optical modulator 12, thereby efficiently preventing warpage.

### Fourth Exemplary Embodiment

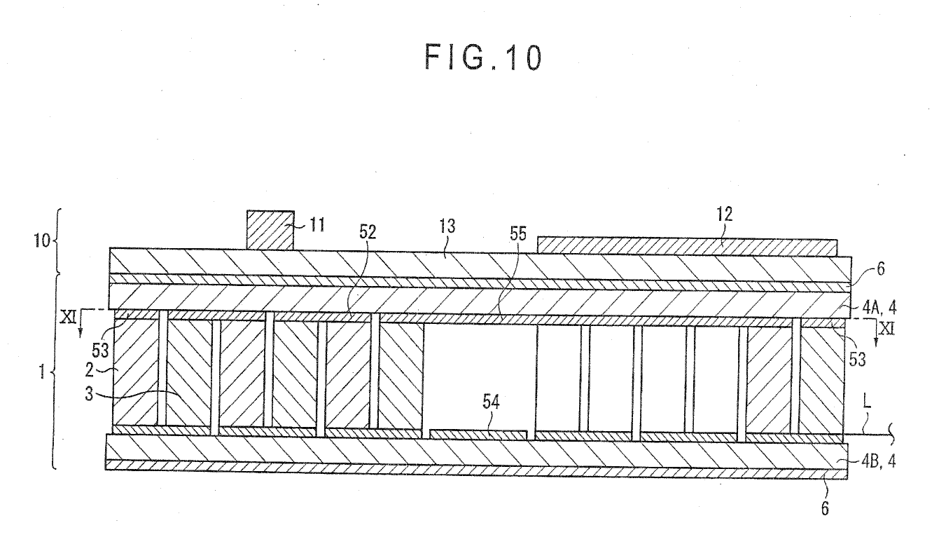

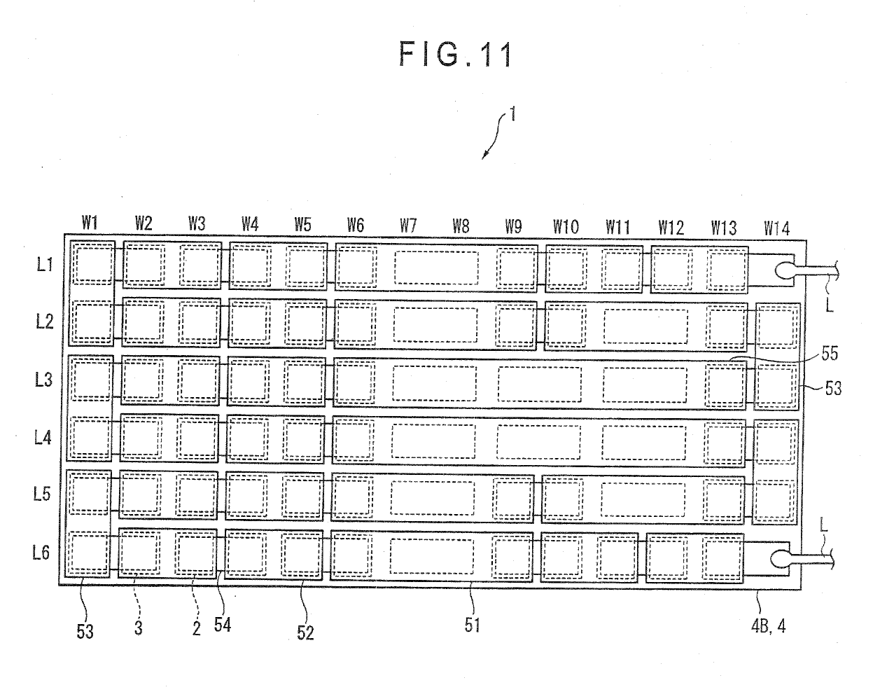

A fourth exemplary embodiment of the invention will be described below with reference to FIGS. 10 and 11.

In the fourth exemplary embodiment, the first electrodes 51 used in the first exemplary embodiment are provided at six positions and the fifth electrodes 55 used in the second exemplary embodiment are provided at two positions.

Also in the fourth exemplary embodiment, 12 pairs (L1 to L6 of W7 and W8 rows, L2 to L5 of W11 and W12 rows and L3 to LA of W9 and W10 rows) of the thermoelectric elements 2 and 3 are eliminated and 29 pairs of the thermoelectric elements 2 and 3 are used. The first electrodes 51 and the fifth electrodes 55 are provided correspondingly to the area where the thermoelectric elements 2 and 3 are eliminated.

According to the thermoelectric module 1 of the fourth exemplary embodiment as described above, an endothermic property and a warpage prevention property, which are substantially intermediate between those in the second and the third exemplary embodiments, are obtained by the electrode pattern applied on the upper substrate 4A.

### Fifth Exemplary Embodiment

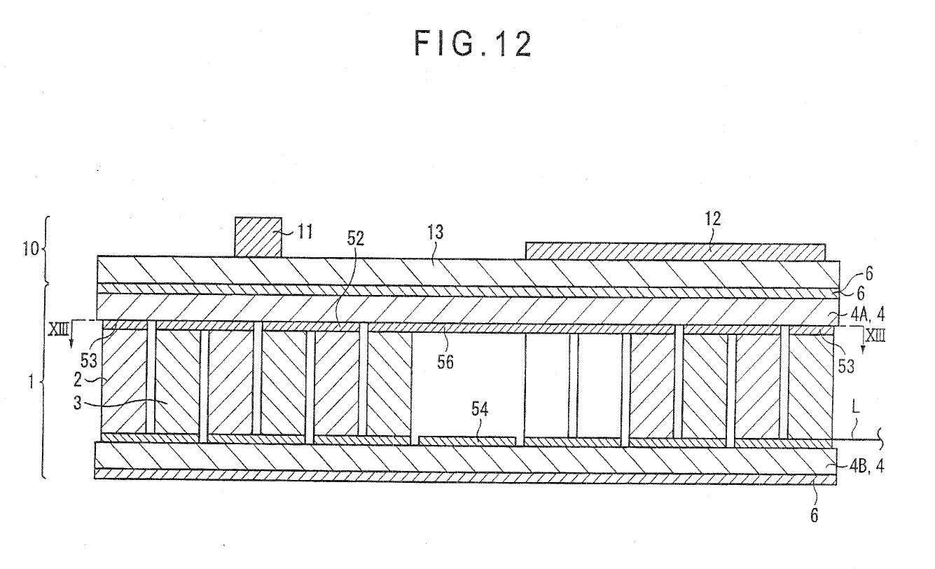

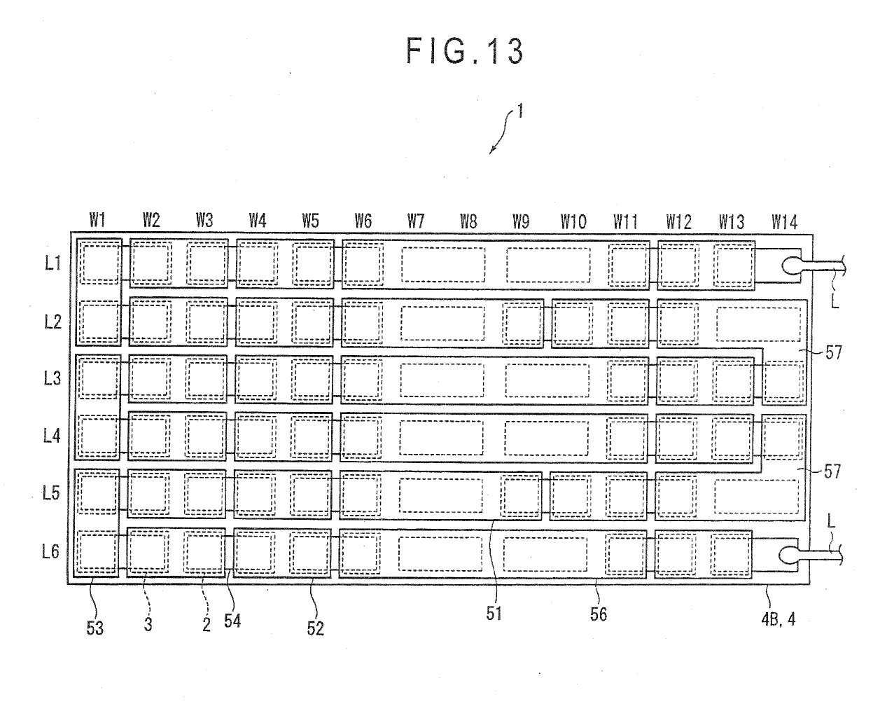

A fifth exemplary embodiment of the invention will be described below with reference to FIGS. 12 and 13.

A distinctive feature of the fifth exemplary embodiment is that the first electrodes 51 of the first exemplary embodiment are provided at two positions, the sixth electrode 56 of the third exemplary embodiment are provided at four positions and seventh electrodes 57 are provided at two positions as an L-shaped bypass electrode to bridge over a single pair.

Also in the fifth exemplary embodiment, 12 pairs (L1, L3, L4 and L6 of W9 and W10 rows, L1 to L6 of W7 and W8 rows and 12 and L5 of W13 and W14 rows) of the thermoelectric elements 2 and 3 are eliminated. In other words, 29 pairs of the thermoelectric elements 2 and 3 are provided between the substrates 4 in the same manner as in the first to fourth exemplary embodiments.

The seventh electrodes 57 connect the thermoelectric elements 2 and 3 in W12 row of L2 line and those in W14 of L3 line as well as the thermoelectric elements 2 and 3 in W12 row of L5 line and those in W14 of L4 line, the seventh electrodes 57 being formed in an L-shaped to bridge over the area where the theunoelectric elements 2 and 3 are eliminated.

According to the thermoelectric module 1 of the fifth exemplary embodiment, substantially the same advantages as in the fourth exemplary embodiment can be obtained in spite of the different electrode pattern of the upper substrate 4A.

Although the best configuration, methods and the like for implementing the invention has been disclosed above, the invention is not limited thereto.

For instance, in the above exemplary embodiments, 12 pairs of the thermoelectric elements 2 and 3 are eliminated from the maximum placement number thereof, whereby 29 pairs of the thermoelectric elements 2 and 3 are provided irrespective of differences of the endothermic efficiency and the warpage property. However, the maximum placement number of the thermoelectric elements 2 and 3 and the number of the thermoelectric elements 2 and 3 to be eliminated (the actual placement number) can be defined as needed and not limited to the above exemplary embodiments. What is necessary is that a substrate including electrodes provided correspondingly to the maximum placement number of the thermoelectric elements 2 and 3 is used in common to the thermoelectric module having different designs.

Though the thermoelectric elements 2 and 3 are series-connected via respective electrodes 51 to 57 in the above exemplary embodiments, the thermoelectric elements 2 and 3 may be parallel-connected.

In the above exemplary embodiments, the first, fifth, sixth and seventh electrodes 51, 55, 56 and 57 serving as a bypass electrode are formed to bridge over the plurality of the theimoelectric elements 2 and 3, but may be formed to bridge over a single pair of thermoelectric elements 2 and 3.

In the above exemplary embodiments, the bypass electrodes are formed on the upper substrate 4A and the fourth electrodes 54 of the maximum placement number are formed on the lower substrate 4B. Alternatively, the bypass electrodes may be formed on the lower substrate 4B and the fourth electrodes 54 of the maximum placement number may be formed on the upper substrate 4A.

As shown in FIG. 7, in the second exemplary embodiment, a plurality (four in the second exemplary embodiment) of the fifth electrodes 55 serving as a bypass electrode are aggregated and the second and third electrodes 52 and 53 are provided in a manner to entirely surround the plurality of the fifth electrodes 55. However, the number of the bypass electrodes surrounded by the second and third electrodes 52 and 53 may be defined as needed. In the aspect of the invention, the second and third electrodes 52 and 53 may surround an entirety of the plurality of the aggregated bypass electrodes or may surround even a single bypass electrode.

What is claimed is:

1. A thermoelectric module, comprising:
a plurality of thetmoelectric elements electrically connected to each other via a plurality of electrodes; and
a pair of substrates including a first substrate and a second substrate on which the plurality of electrodes arc formed on facing surfaces, the pair of substrates being provided perpendicularly to a heat transfer direction with the plurality of thermoelectric elements being interposed, wherein
the plurality of electrodes formed on the first substrate of the pair of substrates include a bypass electrode having a size enough to electrically connect a pair of the thermoelectric elements that are spaced apart by a distance corresponding to an area of one of the theiinoelectric elements or more, and
the plurality of electrodes formed on the second substrate of the pair of substrates are provided correspondingly to a maximum placement number of the plurality of thermoelectric elements interposed between the pair of substrates and have a size enough to electrically connect an adjacent pair of the thermoelectric elements.

2. The thermoelectric module according to claim 1, wherein
the bypass electrode includes a plurality of adjacent bypass electrodes, and bypass-electrode aggregation portion formed by the plurality of adjacent bypass electrodes is surrounded by an electrode having a size enough to electrically connect an adjacent pair of the thermoelectric elements.

3. The thermoelectric module according to claim 1, wherein an object to be cooled is installed on a side opposite to a side of the first or second substrate on which the plurality of electrodes are formed, the plurality of thermoelectric elements are sparsely or densely located in accordance with installation layouts of the object to be cooled, and the bypass electrode has a size enough to connect the pair of thermoelectric elements at dense parts that are located over a sparse part.

4. The thermoelectric module according to claim 7, wherein
an object to be cooled is installed on a side opposite to a side of the first or second substrate on which the plurality of electrodes are foimed,
the plurality of thermoelectric elements are sparsely or densely located in accordance with installation layouts of the object to be cooled, and
the bypass electrode has a size enough to connect the pair of thermoelectric elements at a dense part that are located over a sparse part.
